(19) United States
(12) Patent Application Publication
(10) Pub. No.: US 2008/0079013 A1
(43) Pub. Date: Apr. 3, 2008

(54) LIGHT EMITTING DIODE STRUCTURE

(75) Inventors: Yun-Li Li, Tao-Yung Hsien (TW); Tzu-Chi Wen, Tao-Yung Hsien (TW); Liang-Wen Wu, Tao-Yung Hsien (TW); Chi-Jui Chen, Tao-Yung Hsien (TW); Fen-Ren Chien, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: FORMOSA EPITAXY INCORPORATION, Tao-Yung Hsien (TW)

(21) Appl. No.: 11/535,992

(22) Filed: Sep. 28, 2006

(51) Int. Cl. H01L 33/00

(52) U.S. Cl. 257/96

(57) ABSTRACT

A light emitting diode structure including a substrate, a first type doped semiconductor layer, an insulating layer, light emitting layers, a second type doped semiconductor layer, a first pad and a second pad is provided. The first type doped semiconductor layer is disposed on the substrate. The insulating layer having openings is disposed on the first type doped semiconductor layer for exposing a part of the first type doped semiconductor layer. The light emitting layers are disposed within the corresponding openings of the insulating layer respectively. The second type doped semiconductor layer is disposed on the insulating layer and the light emitting layers. The first pad is disposed on the first type doped semiconductor layer and is electrically connected thereto. The second pad is disposed on the second type doped semiconductor layer and is electrically connected thereto. Besides, air gaps may also be utilized for separating the light emitting layers.

### BACKGROUND OF THE INVENTION

1. Field of Invention

The present invention relates to a light emitting diode (LED) structure. More particularly, the present invention relates to an LED having better light emitting efficiency.

2. Description of Related Art

The light emitting diode (LED) fabricated with the III-V groups of elements compound is a wide bandgap light emitting device, and the light it emits can be almost any light from infrared ray to ultraviolet ray. The light emitting efficiency of an LED device is mainly determined by the internal quantum efficiency of the light emitting layer and the light extraction efficiency, i.e. the external quantum efficiency of the device. The epitaxy quality and structure design of the light emitting layer are improved to increase the internal quantum efficiency thereof, and the key to increase the light extraction efficiency is to reduce the energy loss of the light emitted from the light emitting layer due to the total internal reflection in the LED.

FIG. 1 is a perspective view of a conventional LED chip. Referring to FIG. 1, the conventional LED chip 100 includes a substrate 110, an N-type semiconductor layer 120, a light emitting layer 130, a P-type semiconductor layer 140, an N-type contact pad 150, and a P-type contact pad 160. The N-type semiconductor layer 120 is disposed on the substrate 110, the light emitting layer 130 is disposed on the N-type semiconductor layer 120, and the P-type semiconductor layer 140 is disposed on the light emitting layer 130. As shown in FIG. 1, a part of the N-type semiconductor layer 120 is not covered by the light emitting layer 130 and the P-type semiconductor layer 140. In addition, the N-type contact pad 150 is disposed on the part of the N-type semiconductor layer 120 that is not covered by the light emitting layer 130 and the P-type semiconductor layer 140, and the P-type contact pad 160 is disposed on the P-type semiconductor layer 140.

However, in the foregoing light emitting diode chip 100, the light emitting efficiency of the light emitting layer 130 is still needed to be improved since the light emitting layer 130 is a thin film having only a single light emitting area. In addition, blue shift effect is often produced in the LED chip 100 described above. Thus, how to increase the internal quantum efficiency and avoid blue shift effect in the LED chip by changing the structure of the light emitting layer is to be resolved.

### SUMMARY OF THE INVENTION

Accordingly, the present invention is directed to provide a light emitting diode (LED) structure which has better light emitting efficiency and can avoid blue shift effect.

As embodied and broadly described herein, the present invention provides an LED structure including a substrate, a first type doped semiconductor layer, an insulating layer, a plurality of light emitting layers, a second type doped semiconductor layer, a first pad, and a second pad. The first type doped semiconductor layer is disposed on the substrate. The insulating layer having a plurality of openings is disposed on the first type doped semiconductor layer for exposing a part of the first type doped semiconductor layer. The light emitting layers are respectively disposed within the corresponding openings of the insulating layer such that the light emitting layers can be separated by the insulating layer. The second type doped semiconductor layer is disposed on the insulating layer and the light emitting layers. The first pad is disposed on the first type doped semiconductor layer and is electrically connected to the first type doped semiconductor layer. The second pad is disposed on the second type doped semiconductor layer and is electrically connected to the second type doped semiconductor layer. In an exemplary embodiment of the present invention, the light emitting layers can be separated by air gaps, so that the light emitting layers can be separated without the aforementioned insulating layer having a plurality of openings.

In an exemplary embodiment of the present invention, the material of the substrate is one of silicon, glass, GaAs, GaN, AlGaAs, GaP, SiC, InP, BN, Alumina, or AlN.

In an exemplary embodiment of the present invention, the first type doped semiconductor layer is an n-type semiconductor layer, and the second type doped semiconductor layer is a p-type semiconductor layer.

In an exemplary embodiment of the present invention, the first type doped semiconductor layer includes a buffer layer, a first contact layer, and a first cladding layer. The buffer layer is disposed on the substrate, the first contact layer is disposed on the buffer layer, and the first cladding layer is disposed on the first contact layer.

In an exemplary embodiment of the present invention, the material of the insulating layer includes silicon dioxide.

In an exemplary embodiment of the present invention, the shape of the foregoing openings is polygon.

In an exemplary embodiment of the present invention, the shape of the foregoing openings is round or oval.

In an exemplary embodiment of the present invention, each of the light emitting layers includes a multiple quantum well (MQW) structure.

In an exemplary embodiment of the present invention, the second type doped semiconductor layer includes a second cladding layer and a second contact layer. The second cladding layer is disposed on the insulating layer and the light emitting layers, and the second contact layer is disposed on the second cladding layer.

In overview, according to the LED structure of the present invention, an insulating layer having a plurality of openings is used for dividing or separating the light emitting layer into a plurality of discrete emitting islands, or air gaps are used for separating the light emitting layers so as to increase the internal quantum efficiency. Therefore, the light emitting efficiency of the LED structure can be further enhanced. In addition, the LED structure of the present invention can avoid blue shift effect through the discrete light emitting layers.

In order to make the aforementioned and other objects, features and advantages of the present invention comprehensible, preferred embodiments accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a conventional light emitting diode (LED) chip.

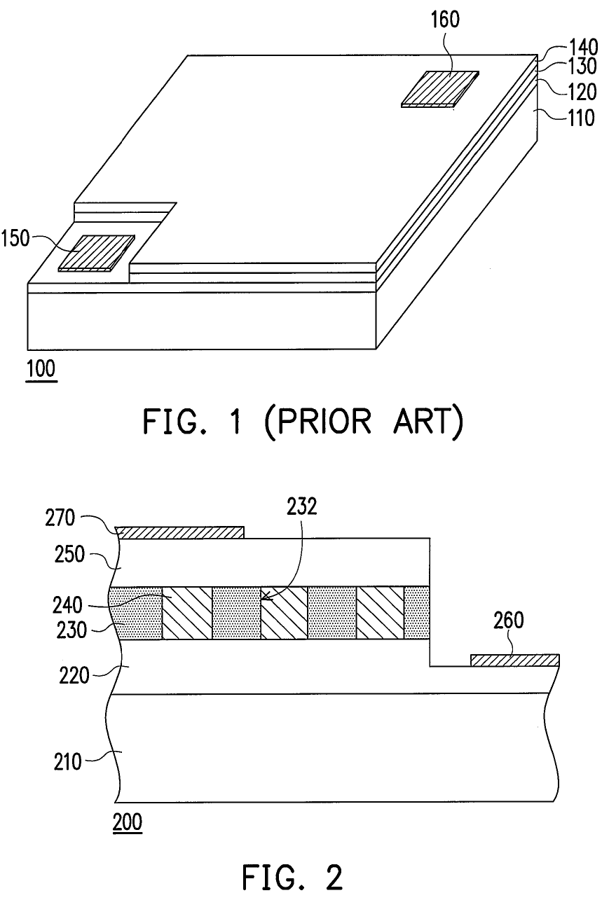

FIG. 2 is a cross-sectional diagram of an LED structure according to the first embodiment of the present invention.

FIGS. 3A˜3C are perspective views of insulating layers having different shapes of openings.

FIG. 4 is a partial cross-sectional diagram illustrating the first type doped semiconductor layer, the light emitting layers, and the second type doped semiconductor layer in an LED chip according to the present invention.

FIG. 5 is a cross-sectional diagram of an LED structure according to the second embodiment of the present invention.

### DESCRIPTION OF EMBODIMENTS

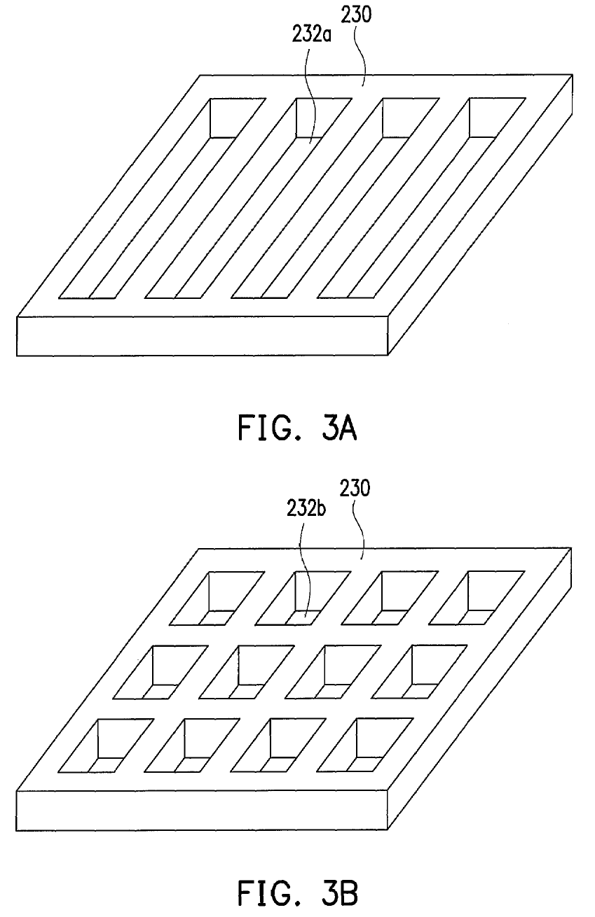

FIG. 2 is a cross-sectional diagram of a light emitting diode (LED) structure according to the first embodiment of the present invention. Referring to the FIG. 2, the LED structure 200 includes a substrate 210, a first type doped semiconductor layer 220, an insulating layer 230, a plurality of light emitting layers 240, a second type doped semiconductor layer 250, a first pad 260, and a second pad 270. The first type doped semiconductor layer 220 is disposed on the substrate 210. The insulating layer 230 having a plurality of openings 232 is disposed on the first type doped semiconductor layer 220 for exposing a part of the first type doped semiconductor layer 220. The light emitting layers 240 are respectively disposed within the corresponding openings 232 of the insulating layer 230. In other words, the light emitting layers 240 are disposed on a part of the first type doped semiconductor layer 220 exposed by the opening 232 of the insulating layer 230. The second type doped semiconductor layer 250 is disposed on the insulating layer 230 and the light emitting layers 240. The first pad 260 is disposed on the first type doped semiconductor layer 220 and is electrically connected to the first type doped semiconductor layer 220. The second pad 270 is disposed on the second type doped semiconductor layer 250 and is electrically connected to the second type doped semiconductor layer 250. In the present invention, the light emitting layers 240 are divided into a plurality of discrete active regions (emitting islands) by the openings 232 of the insulating layer 230, thus, the current distribution in the LED structure 200 is changed so as to increase the internal quantum efficiency, and further the light emitting efficiency of the LED structure 200.

Below, the detailed structure of the foregoing components will be described, but it should be understood that the following description is not for limiting the present invention and those skilled in the art should be able to make various changes in form and details without departing from the spirit and scope of the present invention.

The material of the substrate 210 is semiconductive or non-semiconducting material such as silicon, glass, GaAs, GaN, AlGaAs, GaP, SiC, InP, BN, Alumina, or AlN. The first type doped semiconductor layer 220 is disposed on the substrate 210, and in an embodiment of the present invention, the first type doped semiconductor layer 220 may be, for example, an n-type semiconductor layer.

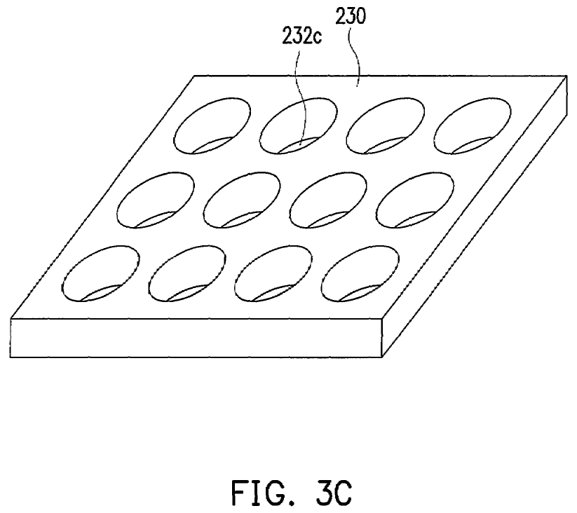

The insulating layer 230 having a plurality of openings 232 is disposed on the first type doped semiconductor layer 220 for exposing a part of the first type doped semiconductor layer 220. In an embodiment of the present invention, the insulating layer 230 can be formed by insulating material such as silicon dioxide. Besides, the foregoing openings 232 may have different shapes, such as polygon, round, oval, or other shapes. FIGS. 3A˜3C are perspective views of insulating layers having different shapes of openings. Referring to FIG. 3A, the insulating layer 230 has a plurality of strip-shaped openings 232a parallel to each other; the insulating layer 230 in FIG. 3B has a plurality of rectangular openings 232b arranged in an array; and the insulating layer 230 in FIG. 3C has a plurality of oval openings 232c arranged in an array. The shape, number, and arrangement of the openings 232 of the insulating layer 230 can be designed according to different application requirement and are not limited in the present invention.

The light emitting layers 240 are respectively disposed within the openings 232 of the insulating layer 230 and are divided into a plurality of discrete emitting islands separated from each other by the openings 232 of the insulating layer 230, so that the light emitting layers 240 form a discontinuous structure. Therefore, the internal quantum efficiency of the LED structure 200 is increased. In an embodiment of the present invention, each of the light emitting layers 240 may be, for example, a GaN/InGaN multiple quantum well (MQW) structure. Besides, a part of the first type doped semiconductor layer 220 that is not covered by the insulating layer 230 and the light emitting layers 240. The second type doped semiconductor layer 250 is disposed on the insulating layer 230 and the light emitting layers 240. The second type doped semiconductor layer 250 may be, for example, a p-type semiconductor layer.

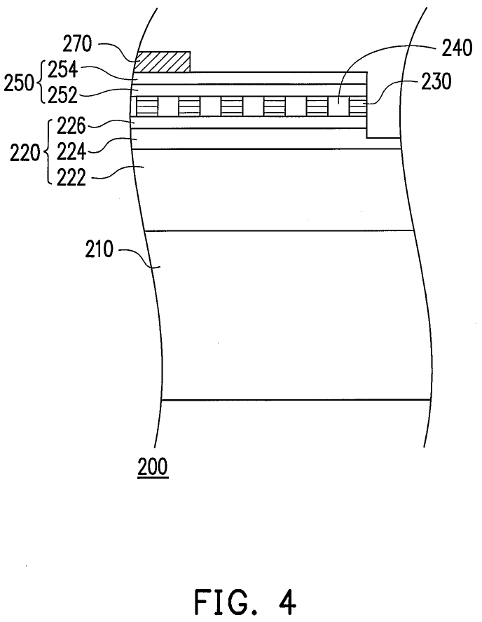

FIG. 4 is a partial cross-sectional diagram illustrating the first type doped semiconductor layer, the light emitting layers, and the second type doped semiconductor layer in an LED chip according to the present invention. Referring to FIG. 4, in an embodiment of the present invention, the first type doped semiconductor layer 220 includes, for example, a buffer layer 222, a first contact layer 224, and a first cladding layer 226. The buffer layer 222 is disposed on the substrate 210, the first contact layer 224 is disposed on the buffer layer 222, and the first cladding layer 226 is disposed on the first contact layer 224. The first cladding layer 226 can be formed by N-doped GaN. The insulating layer 230 and the light emitting layers 230 are disposed on the first cladding layer 226. The second type doped semiconductor layer 250 includes a second cladding layer 252 and a second contact layer 254. The second cladding layer 252 is disposed on the insulating layer 230 and the light emitting layers 230. The second cladding layer 252 can be formed by P-doped GaN. The second contact layer 254 is disposed on the second cladding layer 252. The second contact layer 254 can be formed by P-doped GaN.

Referring to FIG. 2 again, the first pad 260 is disposed on the part of the first type doped semiconductor layer 220 that is not covered by the insulating layer 230 and the light emitting layers 240 and is electrically connected to the first type doped semiconductor layer 220. In an embodiment of the present invention, the material of the first pad 260 may be titanium/aluminum alloy etc. The second pad 270 is disposed on the second type doped semiconductor layer and is electrically connected to the second type doped semiconductor layer 250. Besides, the material of the second pad 270 includes N-type transparent conductive oxide and P-type transparent conductive oxide. The material of the N-type transparent conductive oxide may be ITO, and the material of the P-type transparent conductive oxide is CuAlO₂ etc.

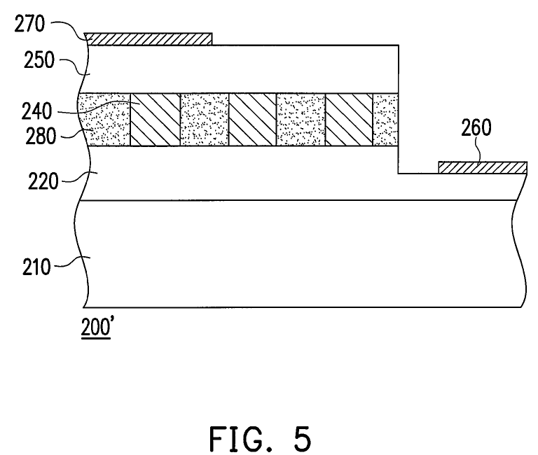

FIG. 5 is a cross-sectional diagram of an LED structure according to the second embodiment of the present invention. Referring to FIG. 5, the LED structure 200′ is similar to the LED structure 200 in FIG. 2. In the present embodiment, there are air gaps 280 between the light emitting layers 240, which mean air gaps are used in the second embodiment for separating the light emitting layers 240. This structure can increase the light emitting efficiency of the LED structure 200′ as well.

To fabricate the LED structure 200′, a plurality of spacers separated from each other are formed on the first type doped semiconductor layer 220 first. Next, the light emitting layers 240 are formed between the spacers. Thereafter, the spacers are removed to form air gaps such that a plurality of light emitting layers 240 separated from each other are formed. Besides, the light emitting layers 240 in FIG. 5 can also be formed with other methods, for example, selective epitaxy. The fabrication method of the light emitting layers 240 in FIG. 5 is not limited in the present invention.

In overview, according to the LED structure of the present invention, an insulating layer having a plurality of openings is used for separating the light emitting layer into a plurality of discrete emitting islands, or air gaps are used for separating the light emitting layers, so as to increase the internal quantum efficiency of the LED structure and further to enhance the light emitting efficiency of the LED structure. In addition, the LED structure of the present invention can avoid blue shift effect through the discrete light emitting layers.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode (LED) structure, comprising:
a substrate;
a first type doped semiconductor layer, disposed on the substrate;
an insulating layer, disposed on the first type doped semiconductor layer, having a plurality of openings for exposing a part of the first type doped semiconductor layer;
a plurality of light emitting layers, disposed within the corresponding openings of the insulating layer respectively;
a second type doped semiconductor layer, disposed on the insulating layer and the light emitting layers;
a first pad, disposed on the first type doped semiconductor layer and electrically connected to the first type doped semiconductor layer; and
a second pad, disposed on the second type doped semiconductor layer and electrically connected to the second type doped semiconductor layer.

2. The LED structure as claimed in claim 1, wherein a material of the substrate is one of silicon, glass, GaAs, GaN, AlGaAs, GaP, SiC, InP, BN, Alumina, or AlN.

3. The LED structure as claimed in claim 1, wherein the first type doped semiconductor layer is an n-type semiconductor layer, and the second type doped semiconductor layer is a p-type semiconductor layer.

4. The LED structure as claimed in claim 1, wherein the first type doped semiconductor layer comprises:
a buffer layer, disposed on the substrate;
a first contact layer, disposed on the buffer layer; and
a first cladding layer, disposed on the first contact layer.

5. The LED structure as claimed in claim 1, wherein a material of the insulating layer comprises silicon dioxide.

6. The LED structure as claimed in claim 1, wherein a shape of the openings is polygon.

7. The LED structure as claimed in claim 1, wherein a shape of the openings is round or oval.

8. The LED structure as claimed in claim 1, wherein each of the light emitting layers comprises a multiple quantum well structure.

9. The LED structure as claimed in claim 1, wherein the second type doped semiconductor layer comprises:
a second cladding layer; and
a second contact layer, wherein the second cladding layer is disposed on the insulating layer and the light emitting layers, and the second contact layer is disposed on the second cladding layer.

10. A light emitting diode (LED) structure, comprising:
a substrate;
a first type doped semiconductor layer, disposed on the substrate;
a plurality of light emitting layers, separated from each other and disposed on the first type doped semiconductor layer;
a second type doped semiconductor layer, disposed on the light emitting layers;
a first pad, disposed on the first type doped semiconductor layer and electrically connected to the first type doped semiconductor layer; and
a second pad, disposed on the second type doped semiconductor layer and electrically connected to the second type doped semiconductor layer.

11. The LED structure as claimed in claim 10, wherein a material of the substrate is one of silicon, glass, GaAs, GaN, AlGaAs, GaP, SiC, InP, BN, Alumina, or AlN.

12. The LED structure as claimed in claim 10, wherein the first type doped semiconductor layer is an n-type semiconductor layer, and the second type doped semiconductor layer is a p-type semiconductor layer.

13. The LED structure as claimed in claim 10, wherein the first type doped semiconductor layer comprises:
a buffer layer, disposed on the substrate;
a first contact layer, disposed on the buffer layer; and
a first cladding layer, disposed on the first contact layer.

14. The LED structure as claimed in claim 10, wherein there are air gaps between the light emitting layers.

15. The LED structure as claimed in claim 10, wherein each of the light emitting layers comprises a multiple quantum well structure.

16. The LED structure as claimed in claim 10, wherein the second type doped semiconductor layer comprises:
a second cladding layer; and
a second contact layer, wherein the second cladding layer is disposed on the light emitting layers and the second contact layer is disposed on the second cladding layer.
